(19) United States
(12) Patent Application Publication
(10) Pub. No.: US 2025/0133743 A1
(43) Pub. Date: Apr. 24, 2025

(54) FERROELECTRIC 3D MEMORY BLOCK UNIT

(71) Applicant: Tokyo Electron Limited, Tokyo (JP)

(72) Inventors: Partha MUKHOPADHYAY, Oviedo, FL (US); Henry Jim FULFORD, Albany, NY (US); Mark I. GARDNER, Albany, NY (US)

(73) Assignee: Tokyo Electron Limited, Tokyo (JP)

(21) Appl. No.: 18/598,907

(22) Filed: Mar. 7, 2024

Related U.S. Application Data
(60) Provisional application No. 63/545,130, filed on Oct. 20, 2023.

(51) Int. Cl. H10B 51/30

(52) U.S. Cl. CPC H10B 51/30

(57) ABSTRACT

FeFET memory devices are provided. A semiconductor device includes a first metal structure of a first gate electrode. The semiconductor device includes a gate dielectric structure extending along a bottom surface of the first metal structure and surrounding a sidewall of the first metal structure. The semiconductor device includes a semiconductor-behaving structure extending along a bottom surface of the gate dielectric structure and surrounding a sidewall of the gate dielectric structure. The semiconductor device includes a ferroelectric structure surrounding a sidewall of the semiconductor-behaving structure. The semiconductor device includes a second gate electrode comprising a second metal structure in contact with the semiconductor-behaving structure.

### CROSS-REFERENCE TO RELATED APPLICATIONS

This application claims priority to U.S. Provisional Application No. 63/545,130, filed Oct. 20, 2023, which is incorporated by reference in its entirety.

### FIELD OF THE DISCLOSURE

This disclosure relates to microelectronic devices including semiconductor devices, transistors, and integrated circuits, including methods of microfabrication. Particularly, the semiconductor devices can include a 3D ferroelectric memory device.

### BACKGROUND

In the manufacture of semiconductor devices (especially on the microscopic scale), various fabrication processes are executed, for example, film-forming depositions, etch mask creation, patterning, material etching and removal, and doping treatments, among others. These processes can be performed repeatedly to form desired semiconductor device elements on a substrate, such as memory devices. Historically, with microfabrication, transistors have been created in one plane, with wiring or metallization formed above the active device plane and have thus been characterized as two-dimensional (2D) circuits or 2D fabrication. Moreover, memory devices formed according to such fabrication typically stored a single bit per transistor. Scaling efforts have greatly increased the number of transistors per unit area in 2D circuits, yet scaling efforts are running into greater challenges as scaling enters single digit nanometer semiconductor device fabrication nodes, and additional memory capacity or density is used. Semiconductor device fabricators have expressed a desire for three-dimensional (3D) semiconductor circuits for high density, high performance memory applications.

### SUMMARY

A multi-bit memory cell includes a semiconductor channel of a GAA transistor, such as a GAA FET. The channel is gated by pair of gate structures which may be disposed, for example, along an inner and outer sidewall of the channel, such that the current flows vertically along the channel according to a voltage of the gate structures. One gate structure can include a gate high-k metal gate stack (HKMG), comprising a high-k dielectric and another dielectric, such as an interfacial dielectric. Another gate structure can include a ferroelectric material configured to polarize upon an application of a control voltage. The HKMG gate can connect to a capacitor to maintain a state thereof, such that both of the gate structures can impose a conductivity modulation to the channel to modulate a flow of current there-through. The capacitor can be formed in a same semiconductor device according to a junction of two conductive portions separated by a dielectric. For example, the capacitor can be formed along a vertical sidewall of an opening in a metal structure formed vertically over the dual-gate transistor, by forming a high-k dielectric along the sidewall and filling the remainder of the opening with another metal structure.

The gates can be employed in a linked manner, to contribute to a same gate voltage, or can be separately controlled. For example, separate control of the gates can be employed for multi-bit operation. An example of multi-bit operation is provided below, where a polarization state of the ferroelectric material is provided as V_{GF}, and a state of the HKMG gate is provided as V_{GS}. Of course, this example, is not limiting, and according to various embodiments, various currents may be realized, and various bit values can be assigned. Moreover, in some embodiments, V_{GF} and V_{GS} may employ non-binary values to realize additional bits:

| V_{GF} | V_{GS} | Bit value |
|---|---|---|
| 0 | 0 | 00 |
| 1 | 0 | 01 |
| 0 | 1 | 10 |
| 1 | 1 | 11 |

The techniques described herein include methods and devices for 3D fabrication of semiconductor devices. Techniques herein can be used for any geometry device (e.g., circular, rectangular, or elliptical). For example, in some embodiments, the transistor may be substantially circular along a lateral plane, with the channel concentrically circumscribed by one gate structure and concentrically circumscribing another gate structure. The capacitor can be formed over the metal portion of the non-ferroelectric gate structure (e.g., a HKMG).

Of course, the order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

At least one aspect of the present disclosure is directed to a semiconductor device. The semiconductor device includes a first metal structure of a first gate electrode. The gate dielectric structure extends along a bottom surface of the first metal structure. The gate dielectric structure surrounds a sidewall of the first metal structure. The semiconductor device includes a semiconductor-behaving structure extending along a bottom surface of the gate dielectric structure and surrounding a sidewall of the gate dielectric structure. The semiconductor device includes a ferroelectric structure surrounding a sidewall of the semiconductor-behaving structure. The semiconductor device includes a second gate electrode comprising a second metal structure in contact with the semiconductor-behaving structure.

In some embodiments, the semiconductor device includes a capacitor having a third metal structure separated from the first metal structure by a capacitor dielectric structure. In some embodiments, the semiconductor device includes an electrical contact electrically connected to the first metal structure vertically extending parallel to the capacitor dielectric structure. The electrical contact can serve as a first terminal of the capacitor. The third metal structure can serve as a second terminal of the capacitor. In some embodiments, the first metal structure is concentric to the sidewall of the gate dielectric structure, the gate dielectric structure is concentric to the sidewall of the semiconductor-behaving structure, and the semiconductor-behaving structure is concentric to the ferroelectric structure. A capacitor dielectric structure can be vertically spaced from the gate dielectric structure, the semiconductor-behaving structure, and the ferroelectric structure.

In some embodiments, the semiconductor device includes a further dielectric structure circumscribing the second metal structure. The ferroelectric structure can be concentric to, circumscribed by, and in contact with the second metal structure. In some embodiments, the third metal structure is connected to a plurality of further capacitor dielectric structures, the plurality of further capacitor dielectric structures configured to maintain a plurality of voltage levels. In some embodiments, the semiconductor-behaving structure comprises a conductive oxide. In some embodiments, a first source/drain contact extends beyond a lateral extreme of the semiconductor-behaving structure. The semiconductor-behaving structure can extend beyond the first source/drain contact in a direction opposite of the lateral extreme. The capacitor dielectric structure and the gate dielectric structure can include a same high-k dielectric material.

At least one aspect of the present disclosure is directed to a semiconductor device. The semiconductor device includes a ferroelectric structure disposed around a second metal structure. The semiconductor device includes a semiconductor-behaving structure separated from a substrate. the semiconductor-behaving structure can vertically extend along a sidewall of, and laterally away from, the ferroelectric structure. The semiconductor device includes a gate dielectric structure extending along an upper surface of the semiconductor-behaving structure and surrounding a sidewall of the semiconductor-behaving structure. The semiconductor device includes a first metal structure surrounding a sidewall of the gate dielectric structure.

In some embodiments, the semiconductor device includes a third metal structure vertically spaced from the first metal structure. The third metal structure can be separated from the first metal structure by a capacitor dielectric structure. The semiconductor device can include an electrical contact electrically connected to the first metal structure vertically extending parallel to a sidewall of the third metal structure, the electrical contact serving as a first terminal of a capacitor, wherein the third metal structure serves as a second terminal of the capacitor. The semiconductor device can include a first dielectric structure interposed between a source/drain contact and the substrate. The capacitor dielectric structure and the gate dielectric structure can include a same high-k dielectric material. In some embodiments, the second metal structure is circumscribed by the ferroelectric structure. The ferroelectric structure can be concentric to, and circumscribed by, the semiconductor-behaving structure. The semiconductor-behaving structure can be concentric to, and circumscribed by, a third dielectric structure. The third dielectric structure can be concentric to and circumscribed by the first metal structure. In some embodiments, the semiconductor-behaving structure comprises a conductive oxide.

At least one aspect of the present disclosure is directed to a method for fabricating semiconductor devices. The method can include forming a ferroelectric structure over, and spaced from, a substrate. The method can include forming a semiconductor-behaving structure laterally spaced from the ferroelectric structure. The method can include forming a first gate structure comprising a first metal portion. The first gate structure can conform to the semiconductor-behaving structure along a first portion of the semiconductor-behaving structure extending in a vertical direction, and a second portion of the semiconductor-behaving structure extending perpendicular to the first portion of the semiconductor-behaving structure. The method can include forming a second gate structure comprising a second metal portion. The second gate structure can conform to the ferroelectric structure along a first portion of the ferroelectric structure extending in the vertical direction, and a second portion of the ferroelectric structure extending perpendicular to the first portion of the ferroelectric structure. The method can include forming a vertical sidewall electrically connected to the first gate structure, and a first electrical contact extending parallel to the vertical sidewall. The method can include forming a high-k dielectric along the vertical sidewall. The method can include forming a terminal comprising a third metal portion over the high-k dielectric.

In some embodiments, the method includes forming a second electrical contact between the substrate and the semiconductor-behaving structure, extending laterally beyond an extreme of the semiconductor-behaving structure, the second electrical contact in contact with the semiconductor-behaving structure along a first face. The method can include forming a third electrical contact between a second face of the semiconductor-behaving structure, opposite from the first face. The method can include forming a fourth electrical contact between in contact with the second metal portion. The method can include forming a fifth electrical contact in electrical contact with the third metal portion. The first electrical contact, the second electrical contact, the third electrical contact, and the fourth electrical contact can extend upwardly beyond a vertical extreme of the high-k dielectric.

In some embodiments, the method includes forming a rail connecting the third metal portion with a plurality of further third metal portions. In some embodiments, the ferroelectric structure is formed along an inner sidewall of the second metal portion. The semiconductor-behaving structure can be formed over an inner sidewall of the ferroelectric structure. The first metal portion can be formed over an inner sidewall of the semiconductor-behaving structure. In some embodiments, the semiconductor-behaving structure is formed over an outer sidewall of the ferroelectric structure. The first metal portion is formed over an outer sidewall of the semiconductor-behaving structure.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 is a flow diagram for a process flow to manufacture semiconductor devices, according to some embodiments.

FIGS. 2-19 illustrate respective views of a semiconductor device during various fabrication stages of the method of FIG. 1, in accordance with some embodiments.

FIGS. 20 and 21 are isometric cross-sectional views of a semiconductor device which may be formed according to the various fabrication stages of the method of FIG. 1, in accordance with some embodiments.

FIG. 22 is another flow diagram for a process flow to manufacture semiconductor devices, according to some embodiments.

FIGS. 23-28 illustrate respective views of a semiconductor device during various fabrication stages of the method of FIG. 22, in accordance with some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Techniques herein include systems and methods for 3D fabrication of semiconductor devices. Specifically, techniques include a vertical gate all around (GAA) ferroelectric conductive oxide junction FET (FeFET) which may operate as an n-bit memory cell. For example, according to the present disclosure, high-speed multibit memory is provided. The memory cells can be arrayed, laterally, or vertically (e.g., stacked). Moreover, a height of either of the FeFET or a capacitor can vary according to a desired refresh rate, channel modulation, etc.

Some advantages with techniques herein include a storage of n-bits of information from a combination of a first gate via ferroelectric material polarization, with another channel such as a HKMG. The ferroelectric polarization can operate as a non-volatile storage (e.g., for years, according to some embodiments). According to various embodiments, the inclusion of a storage capacitor along with a low leakage design of the HKMG can also be non-volatile, or otherwise associated with a lowered refresh rate, lowering power use, SI interference, and so forth.

One embodiment described herein includes a dual gate device configured to store 4 bits. Particularly, the bits may be resolved, by a memory controller according to a current passing through the channel. The current passing through the channel can be modulated by the first and second gates. Other embodiments include additional or fewer bits of operation. For example, other embodiments, can employ additional gates such as a varied drive strength to the two gates depicted herein, or by the employment of additional gates (e.g., along radial or vertical portions of the FeFET).

Reference will now be made to the figures, which for the convenience of visualizing the fabrication techniques described herein, illustrate a variety of materials undergoing a process flow in various views. Unless expressly indicated otherwise, each Figure represents one (or a set) of fabrication steps in a process flow for manufacturing the devices described herein. In the various views of the Figures, connections between conductive layers or materials may or may not be shown. However, it should be understood that connections between various layers, masks, or materials may be implemented in any configuration to create electric or electronic circuits. When such connections are shown, it should be understood that such connections are merely illustrative and are intended to show a capability for providing such connections, and should not be considered limiting to the scope of the claims.

Likewise, although the Figures and aspects of the disclosure may show or describe devices herein as having a particular shape, it should be understood that such shapes are merely illustrative and should not be considered limiting to the scope of the techniques described herein. For example, the techniques described herein may be implemented in any shape or geometry for any material or layer to achieve desired results. In addition, examples in which two transistors or devices are shown stacked on top of one another are shown for illustrative purposes only, and for the purposes of simplicity. Indeed, the techniques described herein may provide for one to any number of stacked devices. Further, although the devices fabricated using these techniques are shown as transistors, it should be understood that any type of electric electronic device may be manufactured using such techniques, including but not limited to transistors, variable resistors, resistors, and capacitors.

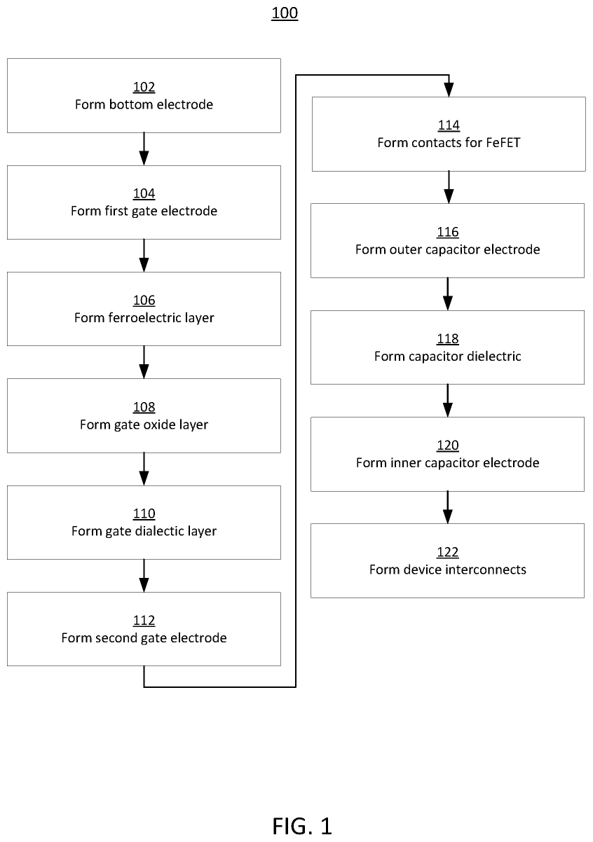

FIG. 1 illustrates a flowchart of an example method 100 for forming a semiconductor device. For example, the semiconductor device can include a plurality of memory cells such as memory cells for a non-volatile memory device. Various memory cells can be interconnected to form arrays. For example, various instances of the memory cells formed according to the method 100 may be laterally spaced from each other (e.g., according to a row or column). Further, various instances of the memory cells formed according to the method 100 may be stacked over each other, such as in a repeating pattern. The various interconnections can be connected to form logical rows, columns, pages, blocks, and so forth.

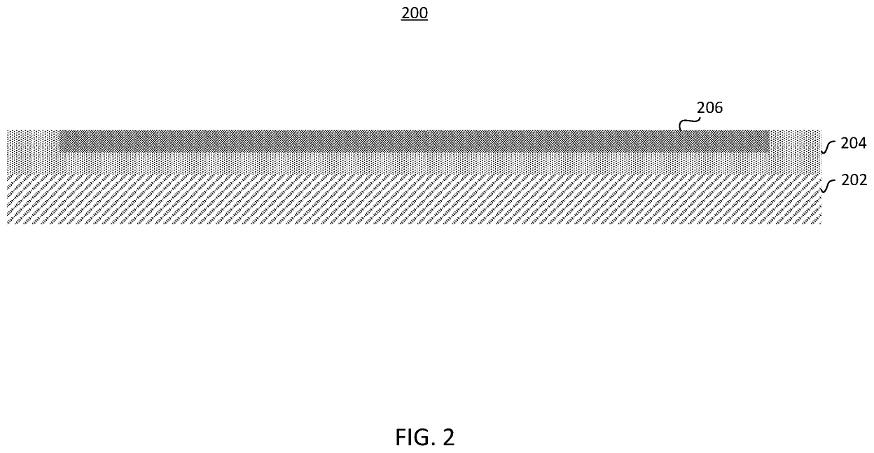

In various embodiments, operations of the method 100 may be associated with top, cross-sectional, or other views of an example semiconductor device at various fabrication stages as shown in FIGS. 2 to 19, which will be discussed in further detail below. It should be understood that the semiconductor device 200, shown in FIGS. 2 to 19, may include a number of other devices such as inductors, fuses, capacitors, coils, etc., while remaining within the scope of the present disclosure. For example, a semiconductor device can include further layers of stacked transistors or channel portions thereof and interconnections therebetween.

In brief overview, the method 100 starts with operation 102 of forming a bottom electrode. The method 100 continues to operation 104 of forming a first gate electrode. The method 100 continues to operation 106 of forming a ferroelectric layer over the semiconductor device. The method 100 continues to operation 108 of forming a gate oxide layer. The method 100 continues to operation 110 of forming a gate dielectric layer. The method 100 continues to operation 112 of forming a second gate electrode. The method 100 continues to operation 114 of forming electrical contact portions. The method 100 continues to operation 116 of forming a first capacitor electrode. The method 100 continues to operation 118 of forming a capacitor dielectric. The method 100 continues to operation 120 of forming a second capacitor electrode. The method 100 continues to operation 122 of forming device interconnects. According to various embodiments, various operations of the method 100 may be omitted, added, modified, or combined.

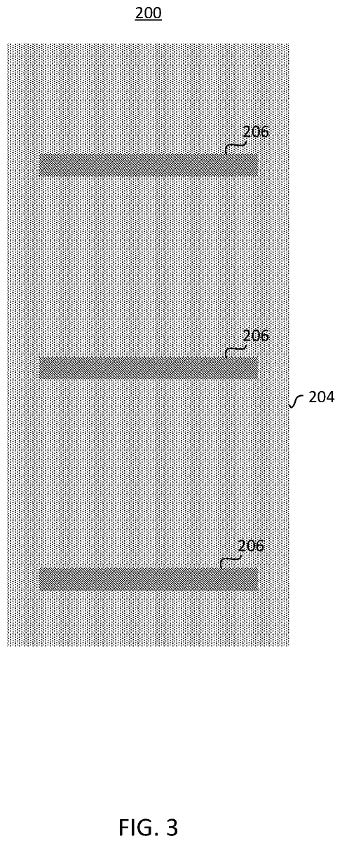

Corresponding to operation 102 of FIG. 1, FIG. 2 is a cross-sectional view of the semiconductor device 200 in which, a metal structure of a bottom electrode 206 is formed. The bottom electrode 206 is spaced from a substrate 202 by a dielectric layer 204. FIG. 3 is a corresponding top view of the semiconductor device, in accordance with some embodiments.

As shown in FIG. 2, a layer of a first dielectric material is formed over the substrate 202 to form a first dielectric layer 204. The substrate 202 includes a glass substrate 202 or semiconductor material substrate 202, for example, silicon. Alternatively, the substrate 202 may include other elementary semiconductor material such as, for example, germanium. The substrate 202 may also include a compound semiconductor such as silicon carbide, gallium arsenic, indium arsenide, and indium phosphide. The substrate 202 may include an alloy semiconductor such as silicon germanium, silicon germanium carbide, gallium arsenic phosphide, and gallium indium phosphide. In one embodiment, the substrate 202 includes an epitaxial layer. For example, the substrate 202 may have an epitaxial layer overlying a bulk semiconductor. Furthermore, the substrate 202 may include a semiconductor-on-insulator (SOI) structure. For example, the substrate 202 may include a buried oxide (BOX) layer formed by a process such as separation by implanted oxygen (SIMOX) or other suitable technique, such as wafer bonding and grinding.

A patternable layer (not depicted), such as a positive or negative photoresist mask with patterns can be formed over the semiconductor device 200. The patternable layer may include a periodic pattern such that periodic openings are formed across the semiconductor device 200, including openings for the depicted bottom electrode 206. The patternable layer may interface with a photoresist, or another material (e.g., hardmask or other mask material) formed into openings of the first patternable layer to form a patterned layer. The upper surface of the semiconductor device 200 and the patternable layer may have different etching selectivity's. For example, the first patternable layer may be more resistive to an etchant than the material of the semiconductor device 200. The upper surface of the semiconductor device 200 can be selectively etched to form openings such as for the depicted bottom electrode 206.

A metal fill is deposited into the opening to form the bottom electrode 206. The metal fill may be formed according to any suitable process, such as physical vapor deposition (PVD), chemical vapor deposition (CVD), electroplating, or so forth. The metal fill (or other conductive layer) may be plarnarized according to a chemical-mechanical grinding/polishing CMG/P process to expose a top surface of the semiconductor device 200.

In some embodiments, an etch stop layer may be formed over the surface of semiconductor device 200. For example, the etch stop layer may be formed over the bottom electrode 206, or the depicted dielectric layer 204. The etch stop layer is further discussed with regard to operation 106. However, as indicated above, the operations disclosed herein are not intended to be limiting, and additional fewer, or different operations can be performed in various sequences.

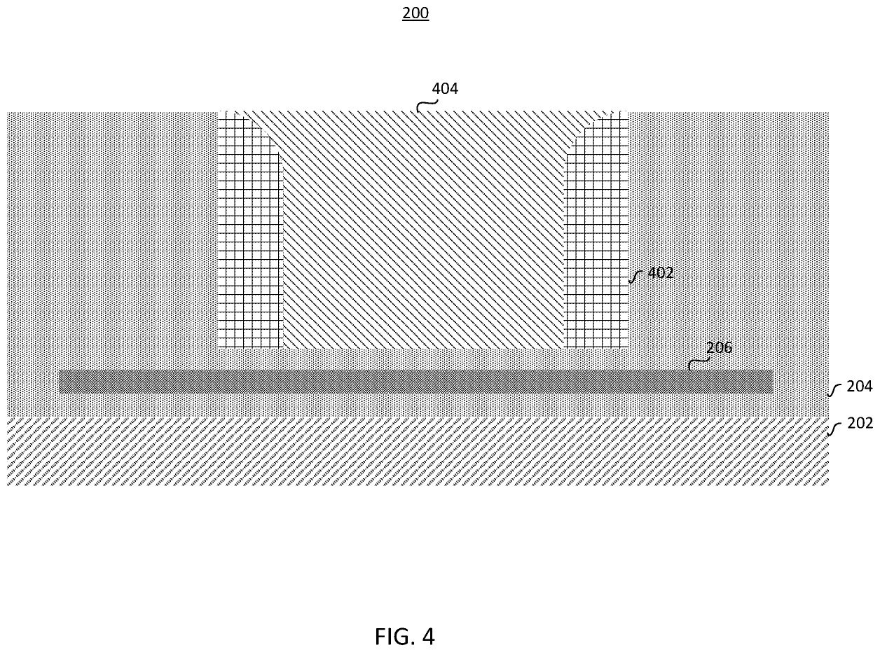

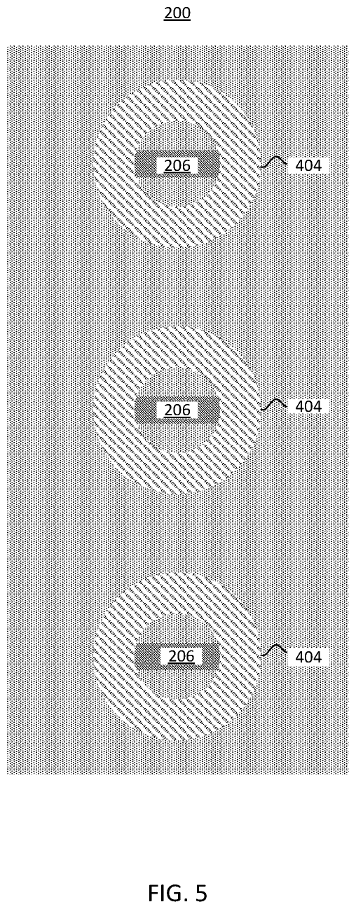

Corresponding to operations 104 and 106 of FIG. 1, FIG. 4, is a cross-sectional view of the semiconductor device 200 in which, a metal structure for a gate structure 402 is formed. At operation 104, the gate structure 402 is spaced from the bottom electrode 206 by a dielectric layer 204. At operation 106, a ferroelectric structure 404 is formed over an opening in the gate structure 402. FIG. 5 is a corresponding top view of the semiconductor device 200, in accordance with some embodiments.

At operation 104, the dielectric layer 204 can be or include a same dielectric or differ from the dielectric of operation 102. Further, the dielectric layer 204 can be deposited according to a same or different process relative to operation 102. An opening is formed in the dielectric layer 204, according to a similar process as described with regard to the bottom electrode 206 opening of operation 102. A metal fill for the gate structure 402 is formed in the opening. The metal fill can be deposited according to a conformal process, such as atomic layer deposition (ALD), or a nonconformal process (e.g., sputtering, CVD, PVD, electroplating, etc.). Where a non-conformal process fills the opening, a central portion of the opening may persist, whereupon at least a portion of such a residual opening may be filled at operation 106. In some embodiments, such as where a non-conformal process fills the opening, an opening can be formed within the metal fill (e.g., according to a positive or negative photo-resist, as described above with regard to the dielectric layer 204). In some embodiments, the metal fill for the gate structure 402 can vary from the metal for the bottom electrode. For example, the gate structure 402 can be configured to interface with a ferroelectric material.

At operation 106, a ferroelectric structure 404 is formed along an inner sidewall of the opening (e.g., the residual opening or other opening formed at operation 104). For example, the ferroelectric material can be deposited according to a conformal process, such as ALD. The ferroelectric material can include, for example, lead zirconate titanate (PZT), Barium Titanate (BaTiO₃), Hafnium Oxide (HfO₂), combinations thereof, or the like. The ferroelectric structure 404 can be annealed or otherwise processed to exhibit a desired ferroelectric property. For example, the ferroelectric property can be adjusted according to a desired conductivity modulation of a channel proximal to the ferroelectric structure 404. The annealing or other processing of the ferroelectric material can be performed during operation 106, or another operation of the method 100.

A lower surface of the opening along an inner facing of the ferroelectric structure 404 can be etched to expose an upper surface of the bottom electrode 206. For example, the semiconductor device 200 can be directionally etched to punch through any ferroelectric material or dielectric formed over the bottom electrode 206. In some embodiments, an isotropic etchant is employed to etch to the etch stop layer of operation 102. The etch stop layer may thereafter be removed such that the bottom electrode 206 can interface with (e.g., directly abut) a semiconductor-behaving structure 602 of operation 108. Thus, as depicted in the top view of FIG. 5, the upper surface of the bottom electrode 206 is visible.

With further reference to FIG. 5, the gate structure 402 is not depicted in the view, according to an isotropic etch used to form the opening for the gate structure 402. In various embodiments, the upper surface of the semiconductor device 200 can include varying ratios of an exposed surface of the ferroelectric structure 404 or the gate structure 402 according to one or more etchants or operations to form the openings, or the gate structure 402 or ferroelectric structure 404 formed therein.

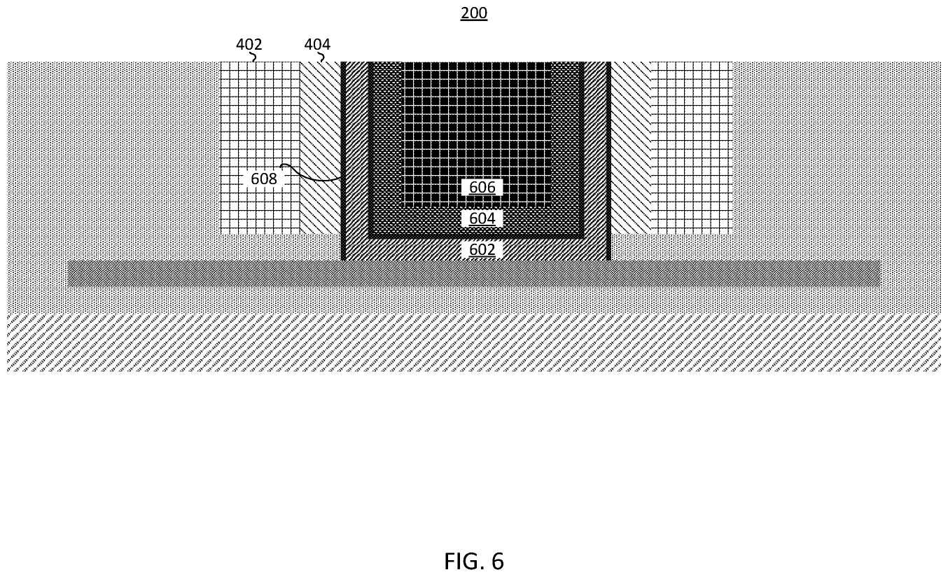

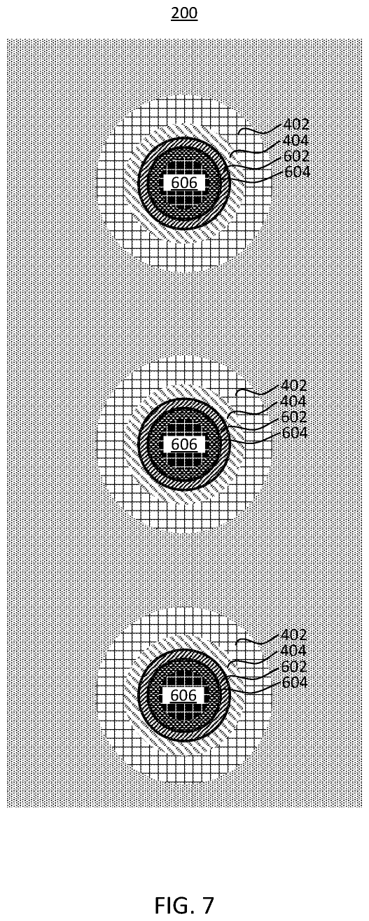

Corresponding to operations 108, 110, and 112 of FIG. 1, FIG. 6 is a cross-sectional view of the semiconductor device 200 in which, at operation 108, a semiconductor-behaving structure 602 is formed according to a conformal process such as an ALD process. At operation 110, a dielectric structure 604 is formed over the semiconductor-behaving structure 602. At operation 112, a metal fill is formed over the dielectric structure 604 to form another gate structure 606. FIG. 7 is a corresponding top view of the semiconductor device 200, in accordance with some embodiments.

At operation 108, a semiconductor-behaving structure 602 is formed over the bottom electrode 206. In some embodiments, the semiconductor-behaving structure 602 can be formed directly over (e.g., in contact with) the bottom electrode 206. For example, an interfacial dielectric layer 608 can be conformally formed (e.g., by an ALD process) over the opening defined by the ferroelectric structure 404, and thereafter directionally etched to remove the interfacial dielectric layer 608 from the bottom of the opening, leaving at least a portion of the interfacial dielectric layer 608 along the sidewalls of the opening, such that upon the formation of the semiconductor layer for the semiconductor-behaving structure 602, the interfacial dielectric layer 608 separates the semiconductor-behaving structure 602 from the ferroelectric structure 404 and does not separate the semiconductor-behaving structure 602 from the bottom electrode 206. The semiconductor-behaving structure 602 can include a conductive oxide (e.g., zinc oxide (ZnO), Indium Gallium Zinc Oxide (IGZO), Indium Oxide (In₂O₃), Tin Oxide (SnO₂), Gallium Oxide (Ga₂O₃), Nickel Oxide (NiO), the like, and combinations thereof). The dielectric structure 604 may be referred to as a gate dielectric structure, either singularly, or in combination with another depicted or undepicted portion, such as an interfacial dielectric layer 608.

The semiconductor-behaving structure 602 can serve as a channel for the semiconductor device 200. The channel can extend, vertically, between the bottom electrode 206 and a top electrode formed at operation 114. The channel can be bounded by the gate structure 402 of operation 104 and 106, which may be referred to as an outer gate, and the other gate structure depicted herein (comprising the dielectric structure 604 and the metal gate structure 606) which may be referred to as an inner gate. Thus, a conductivity of the channel can be modulated by either or both of the gates to correspond to various bit values (when employed as a memory device) or other signals according to a particular application.

At operation 110, another dielectric layer is formed over the semiconductor-behaving structure 602. For example, the dielectric layer can be formed from (or include) a high-k (e.g., a material having a dielectric constant exceeding that of silicon dioxide, such as hafnium oxide). The dielectric material can be selected to form a dielectric structure 604 of a high-k metal gate (HKMG). The HKMG or other gate can further include an interfacial dielectric layer 608. For example, the interfacial dielectric layer 608 may include a same material as the interfacial dielectric layer 608 separating the channel from the outer gate. The dielectric structure 604 can extend along a bottom surface of the gate structure 606 and surround a sidewall of the gate structure 606. The semiconductor-behaving structure 602 can extend along a bottom surface of the dielectric structure 606 and can surround a sidewall of the dielectric structure 604. The references to surrounding are not intended to require surrounding in every dimension. For example, as depicted in FIG. 6, the ferroelectric structure 404 can be referred to as surrounding the semiconductor-behaving structure 602 (e.g., according to various lateral planes, as depicted in FIG. 7).

At operation 112, a metal fill is deposited according to any suitable process (e.g., electroplating or another fill process) to form a gate structure 606 for an inner gate. For example, as depicted, the metal fill can be deposited directly over the dielectric structure 604. The semiconductor device 200 can thereafter be planarized to form the depicted upper surface. That is, the entrant profile depicted in FIG. 4, may be removed to leave substantially vertical sidewalls between the various depicted portions.

Thus, as depicted in the top view of FIG. 7, the metal portion of the gate structure 606 for an inner gate is circumscribed by, and concentric to, the dielectric structure 604. The dielectric structure 604, in turn, is circumscribed by, and concentric to, the semiconductor-behaving structure 602. The semiconductor-behaving structure 602, in turn, is circumscribed by, and concentric to, the ferroelectric structure 404. The ferroelectric structure 404, in turn, is circumscribed by, and concentric to, the gate structure 402.

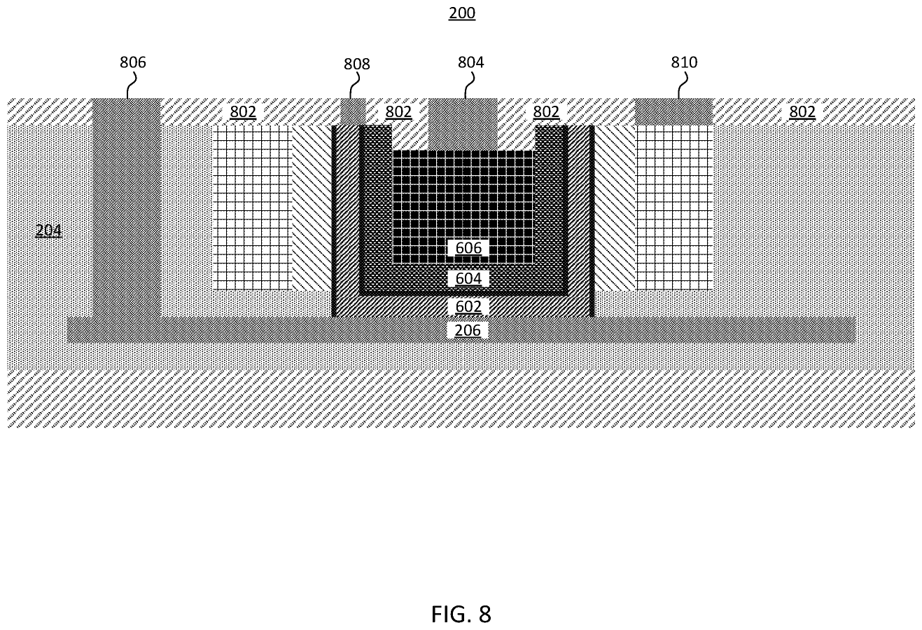

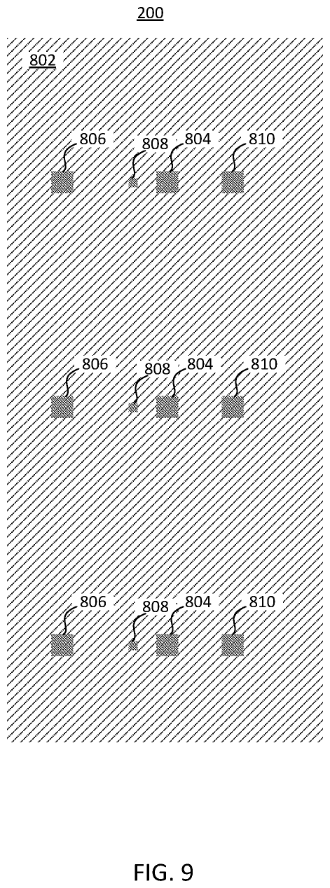

Corresponding to operation 114 of FIG. 1, FIG. 8 is a cross-sectional view of a semiconductor device 200 in which conductive contacts are formed to connect to various structures of the semiconductor device 200. The contacts extend through a dielectric layer 802 formed over the semiconductor device 200. FIG. 9 is a corresponding top view of the semiconductor device 200, in accordance with some embodiments.

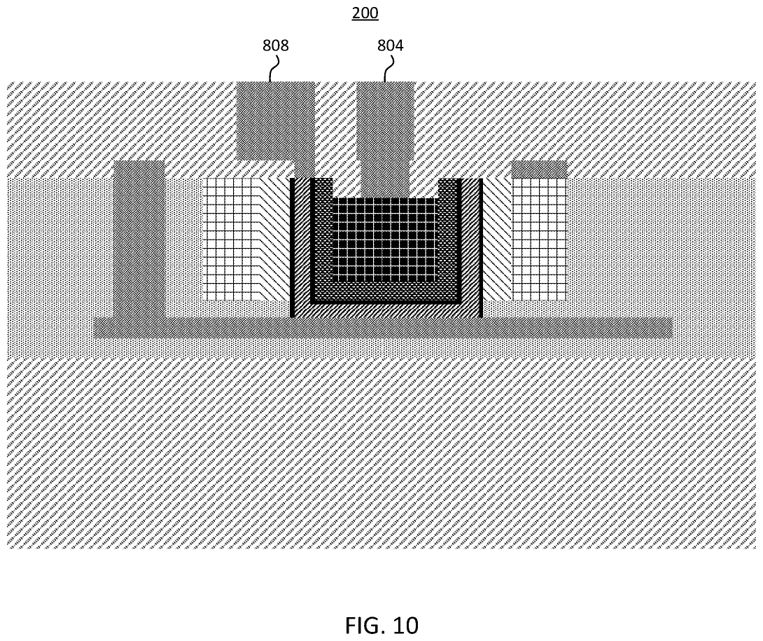

The dielectric layer 802 can include a same or different dielectric relative to the dielectric layer 204 of operation 102. Openings can be formed in the dielectric layer 802 (e.g., according to a positive or negative photoresist as discussed with regard to operation 102). The openings are then filled with a metal fill to form the depicted contacts. For example, the openings can be filled as depicted according to a first sub-operation, and the contacts can be extended, as depicted by FIG. 10 at another suboperation. In another example, the contact portions depicted in FIGS. 8, 9, 10, and 11 are formed according to a same metal fill. That is, a double damascene process may be employed.

Particularly, the contacts include a first contact 804 to electrically connect to the metal gate structure 606 of the inner gate. A second contact 806 can be in contact with the second electrode (e.g., through various dielectric layers 204, 802). The second contact 806 can connect, via the bottom electrode 206 beyond a lateral extreme of the semiconductor-behaving structure 602, to a first face of the semiconductor-behaving structure 602 (e.g., a first drain/source). Opposite therefrom, the semiconductor-behaving structure 602 can extend beyond the bottom electrode 206. A third contact 808 can electrically connect to a second face of the semiconductor-behaving structure 602, opposite the first face, such that a channel is formed between the second contact 806 and the third contact 808, through the semiconductor-behaving structure 602. That is, the second contact 806 and third contact 808 can be source/drain contacts. A fourth contact 810 can electrically connect to a gate structure 402 for the outer gate.

Referring again to the second contact 806, an opening for the contact can extend through the other dielectric layers to extend to the bottom electrode 206. For example, the vertical opening extending from the surface of the semiconductor device 200 can be formed in a same operation as the openings in the dielectric layer 802 formed thereover, or according to multiple sub-operations. That is, a first sub-operation can form an opening in the dielectric layer 204 over the bottom electrode 206, wherein a second sub-operation can form an opening in the other dielectric layer 802. Likewise, the opening may be filled with a metal fill according to one or more suboperations.

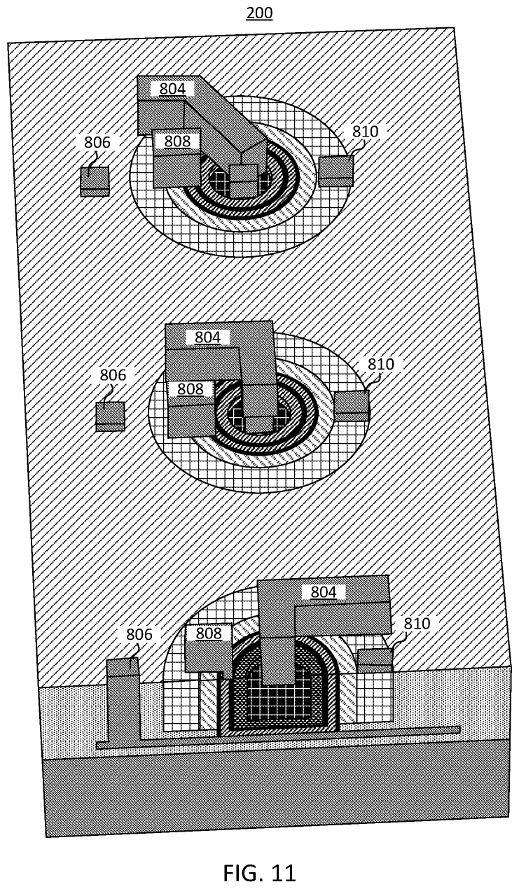

With continued correspondence to operation 114 of FIG. 1, FIG. 10 is a cross-sectional view of a semiconductor device 200 in which the first contact 804 and the third contact 808 are extended upward. The vertical extensions can include various patterns, such as patterns extending laterally over a surface of the semiconductor device 200. Various orientations of one or more contacts can be a same or different orientation as each other, according to a desired routing for the semiconductor device 200. Referring now to FIG. 11, some example contacts are provided, illustrating some example orientations. Merely for depiction of the various features, a portion of the dielectric layer 802 is omitted in the view. Thus, the depicted first contact 804 and third contact 808, which extend to a surface of the semiconductor device 200 are depicted along with, for example, the second contact 806 and fourth contact 810 which, as depicted in FIG. 10, extend to a relatively inferior vertically position.

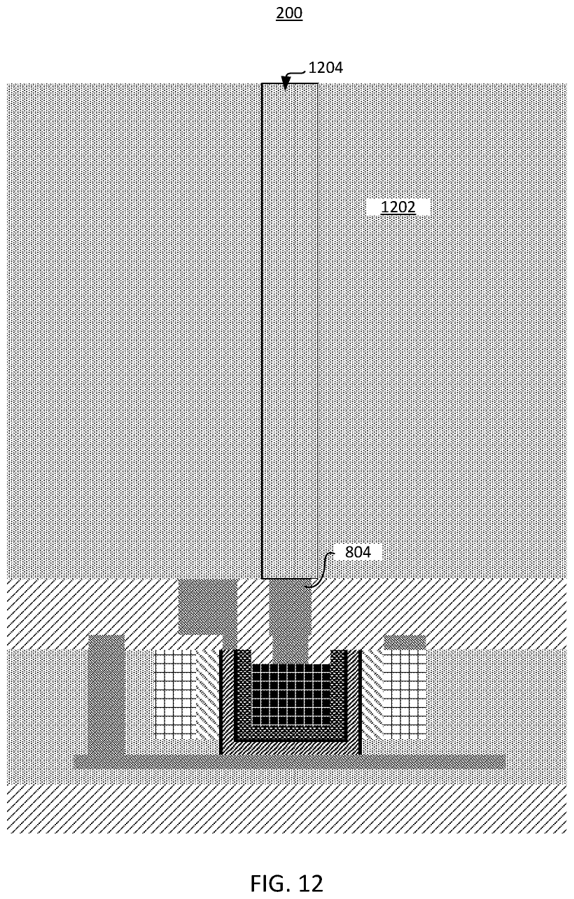

Corresponding to operation 116 of FIG. 1, FIG. 12, depicts a formation of an opening 1204 for an outer capacitor electrode, according to some embodiments. The outer capacitor electrode can be formed in an opening 1204 of a dielectric formed over the semiconductor device 200. The opening 1204 extends to the upper surface of the first contact 804. For example, an etchant to form the opening can be selective to the dielectric material of the dielectric layer 1202, or an etch stop layer can be formed over the first contact 804, incident to operation 114.

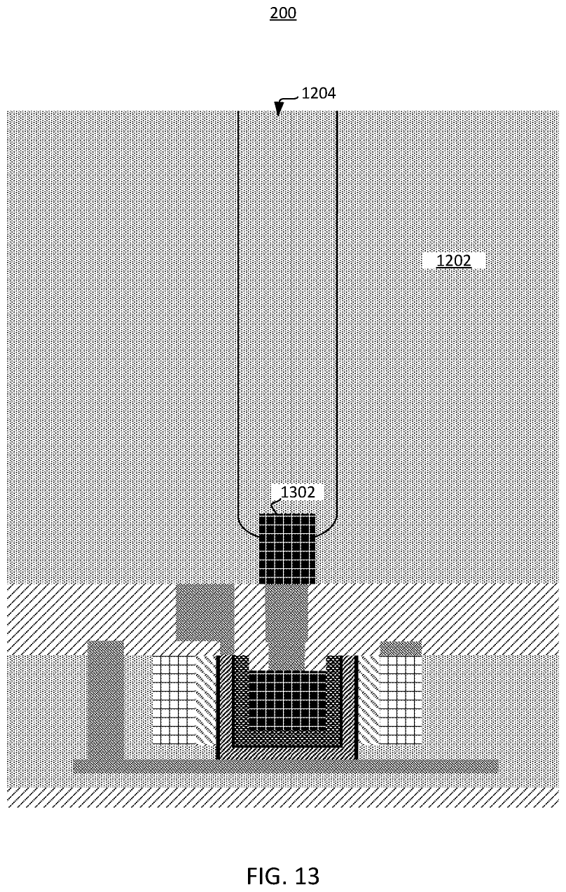

The first contact 804 can be, include, or be referred to as the outer capacitor electrode without limiting effect. Likewise, the outer capacitor electrode can be, include, or be referred to as the first contact 804. For example, as is depicted in FIG. 13, with continued correspondence to operation 116, a metal fill is depicted contacting the first contact 804 formed at operation 114. The first capacitor electrode structure 1302 is depicted as an outer electrode, though a particular geometry of the capacitor 2002 can vary according to various embodiment of the present disclosure. The depicted portion of the first capacitor electrode structure 1302 can be formed according to a metal fill and planarization, metal fil and etch back (e.g., a wet etchant selective to a metal of the first capacitor electrode structure 1302, relative to the dielectric layer 1202), or any other suitable process. As further depicted in FIG. 13, the opening 1204 is expanded to a larger diameter according to, for example, an isotropic etchant selective to the dielectric layer 1202, relative to the metal fill.

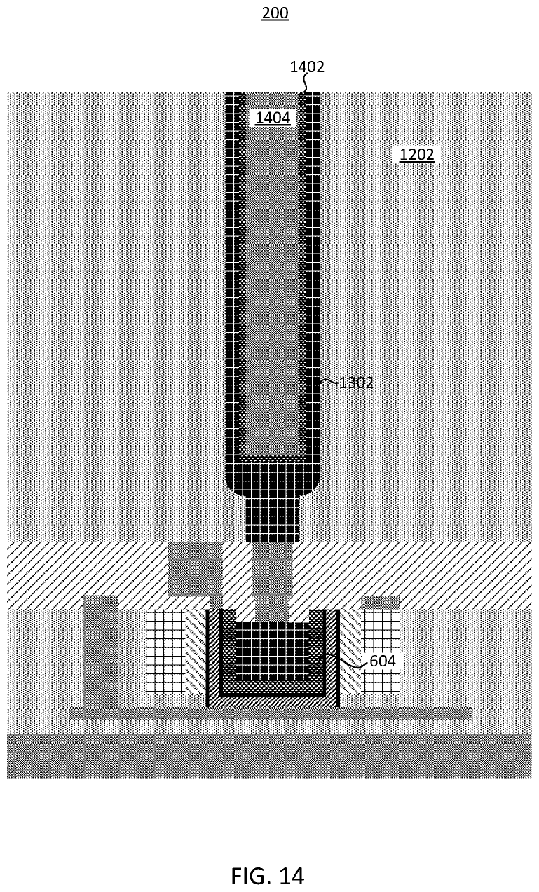

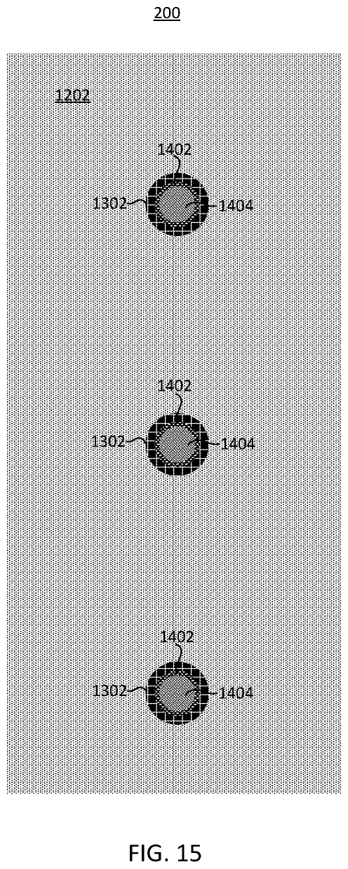

With continued correspondence to operation 116, as well as correspondence to operations 118 and 120 of FIG. 1, FIG. 14 is a cross-sectional view of the semiconductor device 200 in which, at operation 116 another portion of the outer capacitor electrode is formed within the opening 1204 of FIG. 12. At operation 118, a capacitor dielectric structure 1402 is formed over the first capacitor electrode structure 1302. At operation 120, a second capacitor electrode structure 1404 is formed over the capacitor dielectric structure 1402. FIG. 15 is a corresponding top view of the semiconductor device 200, in accordance with some embodiments.

At operation 116, vertical sidewalls of the first capacitor electrode structure 1302 are formed along the sidewalls of the opening 1204. The first capacitor electrode structure 1302 can be formed according to a conformal (e.g., ALD) process, or can be deposited into the opening 1204 and an opening 1204 can be formed therein. At operation 118, a capacitor dielectric structure 1402 is formed along the first capacitor electrode structure 1302. The capacitor dielectric structure 1402 can be formed according to an ALD process. A dielectric material of the capacitor dielectric structure 1402 can include a high-k dielectric. For example, the high-k dielectric can include a same high-k dielectric as the dielectric structure 604 of a high-k metal gate (HKMG). At operation 120, a second capacitor electrode structure 1404 is formed in the opening 1204. The second capacitor electrode structure 1404 can be formed according to a metal fill process. An upper surface of the semiconductor device 200 can thereafter be planarized to reveal the dielectric layer 1202 circumscribing the first capacitor electrode structure 1302, circumscribing the capacitor dielectric structure 1402, circumscribing the residual metal fill of the second capacitor electrode structure 1404. FIG. 15 depicts such a top view, according to some embodiments.

According to various embodiments, operations 116, 118, and 120 can be performed according to various sequences, or can be repeated. In various embodiments, the capacitor 2002 can be formed with various geometries, such as a lower outer electrode connected to the first contact 804 or a lower inner electrode connected to the first contact 804. Further, various operations may be repeated, such as to form a capacitor 2002 including multiple vertical sidewalls such as a multi-layer capacitor 2002. Likewise, as depicted and according to various further geometries, at least a portion of the capacitor dielectric structure 1402 can extend laterally over a surface of the semiconductor device 200.

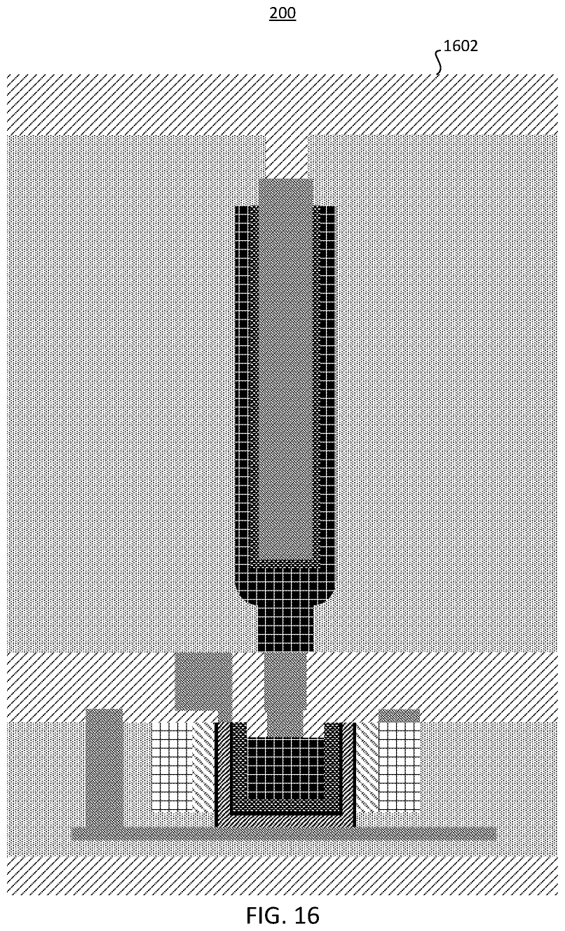

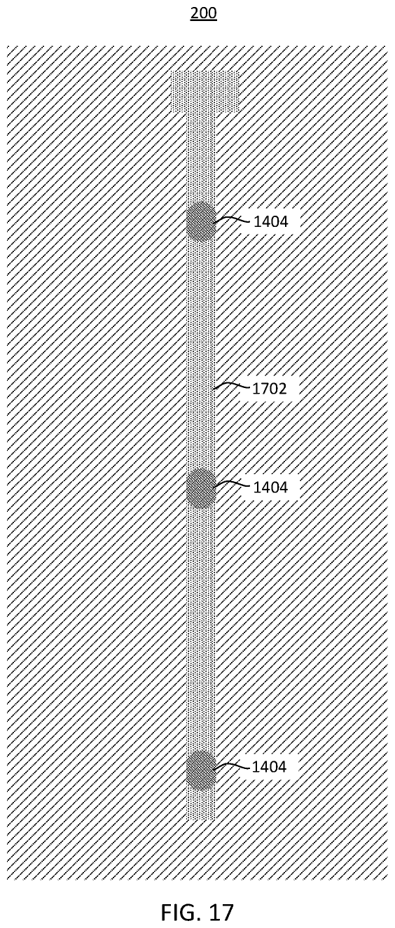

Corresponding to operation 122 of FIG. 1, FIG. 16 is a cross-sectional view of the semiconductor device 200 in which, the first capacitor electrode structure 1302 and the capacitor dielectric structure 1402 are recess etched to electrically isolate the second capacitor electrode structure 1404 from the first capacitor electrode structure 1302 (e.g., the fourth contact 1810 extends upwardly beyond a vertical extreme of the capacitor dielectric structure 1402). FIG. 17 is a corresponding top view of the semiconductor device 200, in accordance with some embodiments.

In some embodiments, the second capacitor electrode structure 1404 and the first capacitor electrode structure 1302 can include different materials, such that an etchant which is selective to the different materials can be employed in the recess etch. According to some embodiments, the second capacitor electrode structure 1404 can be otherwise extended, such as by selectively seeding a material of the second capacitor electrode structure 1404 and extending the second capacitor electrode structure 1404, relative to the first capacitor electrode structure 1302.

Thereafter, a patternable layer 1602 is formed over the semiconductor device 200 to define an interconnect between a plurality of the depicted structures (e.g., capacitors 2002 thereof). For example, the patternable layer 1602 can define a power rail (e.g., ground rail) to connect the capacitors 2002. Thus, the power rail can define a shared voltage (e.g., ground voltage) of the various capacitors 2002, and the capacitors 2002 (e.g., the capacitor dielectric structure 1402 thereof) can store a charge at an opposite terminal of the capacitor 2002. That is, the capacitor 2002 can store a charge proximal to the first contact 804.

As depicted in FIG. 17, the patternable layer 1602 can define an opening 1702, the opening 1702 formed by a stripping the photoresist of FIG. 16. The opening 1702 can thereafter be filled with a conductive (e.g., metal) element to interconnect the upper capacitor electrodes.

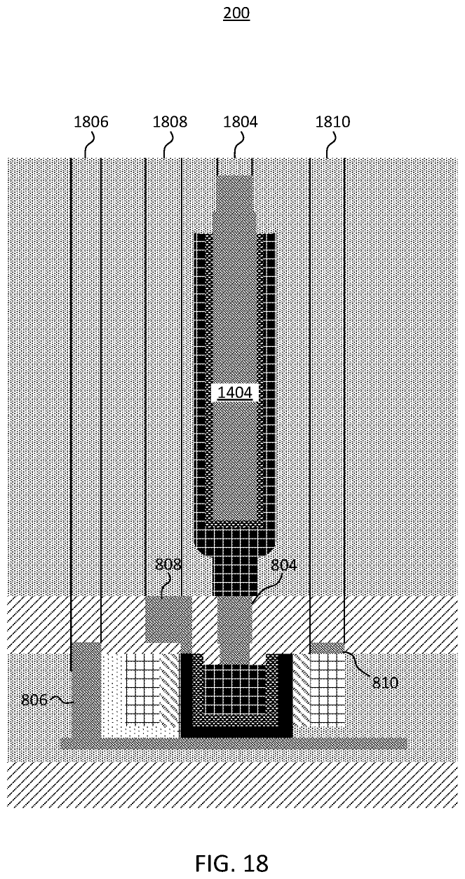

With continued correspondence to operation 122 of FIG. 1, FIG. 18 is a cross-sectional view of the semiconductor device 200 in which, openings are formed to correspond to various contacts of the semiconductor device 200. For example, a first opening 1804 can extend to a first contact 804 which is laterally rotated (as depicted in FIG. 11) to various positions. For example, as depicted, the first opening 1804 can extend to a first contact 804 located behind the second capacitor electrode structure 1404 according to the cross-sectional view of FIG. 18. As further depicted in FIG. 11, the first contact 804 can be positioned at various locations in various embodiments. Further, other contacts can be so positioned, according to a desired routing.

Further, a second opening 1806 extends to the second contact 806, a third opening 1808 extends to the third contact 808, and a fourth opening 1810 extends to the fourth contact 810. A fifth opening (not depicted) can extend to an electrode of the capacitor 2002 disposed across the capacitor dielectric structure 1402 from the first contact 804. The fifth opening (not depicted) can correspond to any number of capacitors 2002, such as a single fifth opening for a power rail, the power rail connected to any number (e.g., one or more) capacitors 2002.

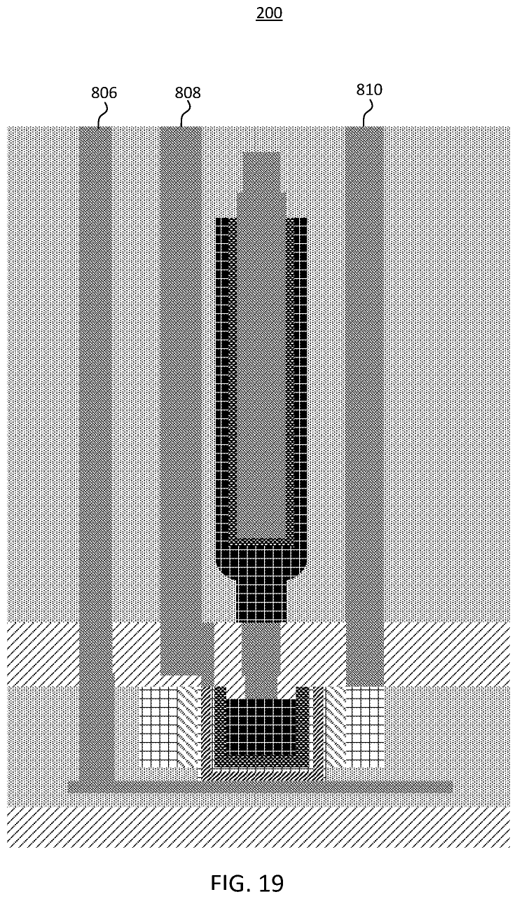

With continued correspondence to operation 122 of FIG. 1, FIG. 19 is a cross-sectional view of the semiconductor device 200 in which, openings are filled with a metal to extend various electrical contacts, according to some embodiments.

The first opening 1804 is not depicted as filled to prevent confusion with the upper electrode of the capacitor 2002. Such an embodiments may correspond to, for example, a first contact 804 which is rotated away from a cut plane of the depicted cross-sectional view. Each of the second contact 806, the third contact 808, and the fourth contact 810 extend to a surface of the semiconductor device 200. A fifth contact (not depicted) can connect to the upper capacitor electrode (e.g., directly, or via a power rail) according to a same operation or suboperation. For example, a metal fill operation can form the contact extensions, wherein a planarization operation such as a CMG/P operation can planarize a surface of the semiconductor device 200.

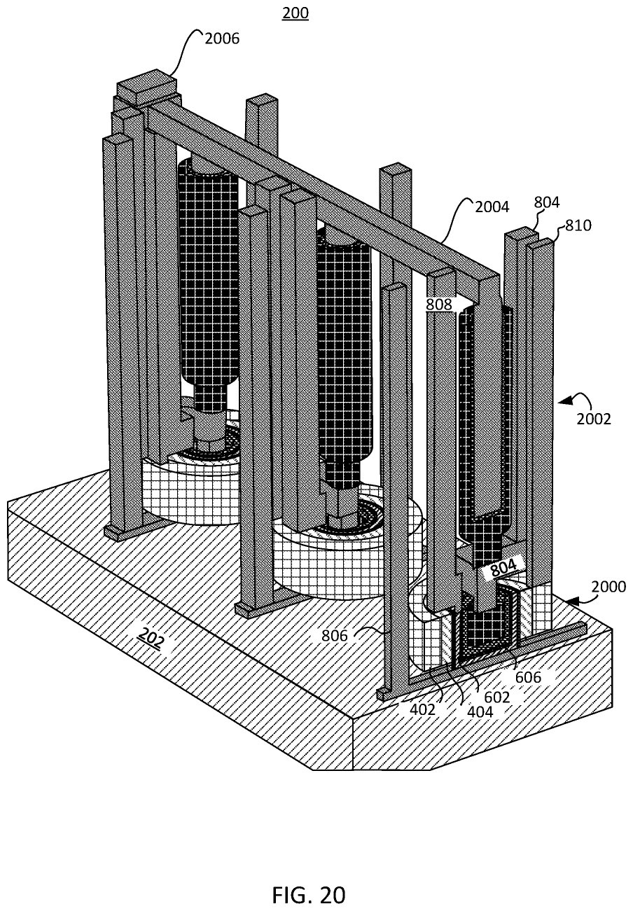

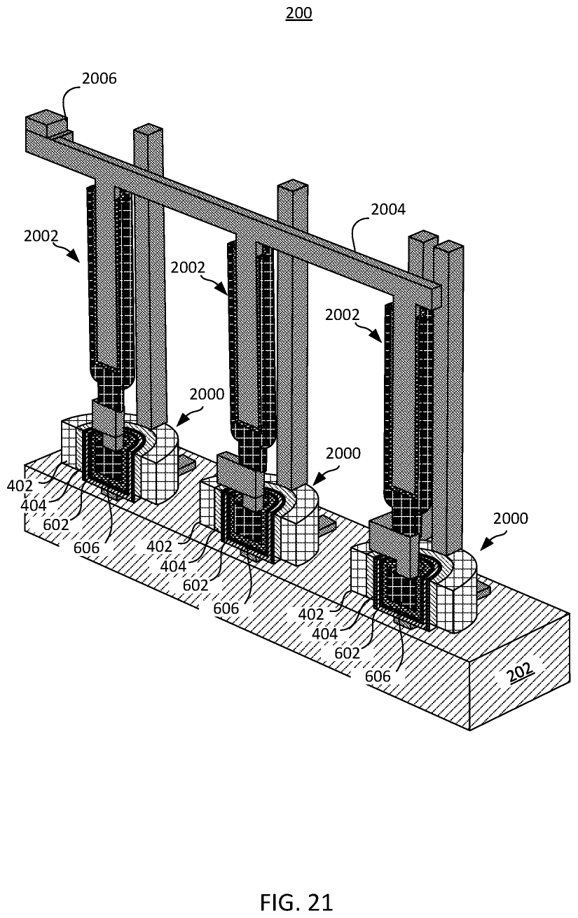

FIG. 20 is a cross-sectional view of a semiconductor device 200 which may be formed according to the various fabrication stages of the method 100 of FIG. 1, in accordance with some embodiments. FIG. 21 is a corresponding cross-sectional view of the semiconductor device 200 along a perpendicular cut plane, in accordance with some embodiments. In each of FIG. 20 and FIG. 21, various dielectric layers are omitted to aid in a clarity of depiction of other features of the semiconductor device 200.

A ferroelectric field effect transistor (FeFET) 2000 is formed over and spaced from a substrate 202. A capacitor 2002 is formed over the FeFET 2000. The FeFET 2000 includes a channel formed from a semiconductor-behaving structure 602. The channel is gated by a gate structure 402 corresponding to a ferroelectric material such that a polarization of the ferroelectric structure 404 modulates a channel current. The channel is gated by a gate structure 606 corresponding to a HKMG such that an electrical charge along a high-k material further modulates the channel current. The electrical charge can be maintained by the capacitor 2002, such that the gate structure 606 maintains a non-volatile state or reduces a refresh rate associated therewith.

A first contact 804 can charge (or discharge) the capacitor 2002 to control a state of the HKMG gate structure 606. As depicted, the first contact 804 extends, upwardly, parallel to the capacitor sidewalls and the capacitor dielectric structure 1402 of the capacitor 2002. A second contact 806 and third contact 808 connect to opposite faces of the vertical channel (e.g., are first and second source/drain contacts). A fourth contact 810 connects the gate structure 402 corresponding to a ferroelectric material. A fifth contact 2006 connects to an upper electrode of the capacitor 2002 (via a power rail 2004).

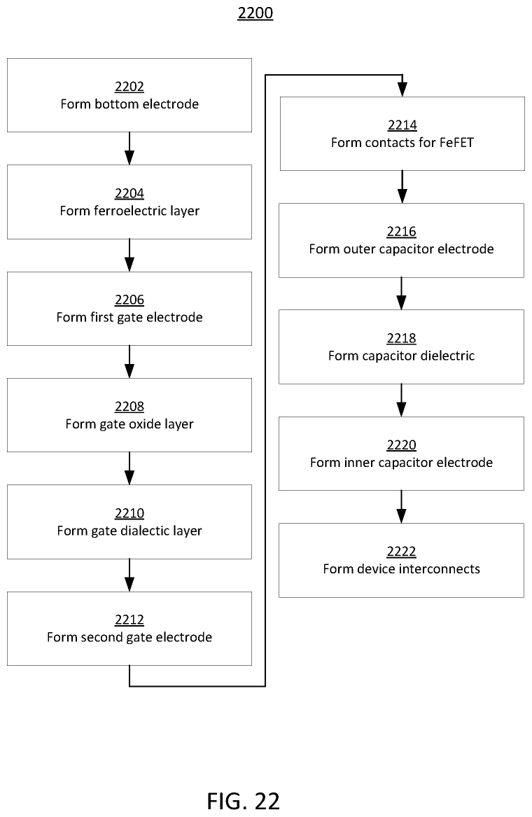

FIG. 22 illustrates a flowchart of an example method 2200 for forming a semiconductor device 200. For example, the semiconductor device 200 can include a plurality of memory cells such as memory cells for a non-volatile memory device. Various memory cells can be interconnected to form arrays. For example, various instances of the memory cells formed according to the method 2200 may be laterally spaced from each other (e.g., according to a row or column). Further, various instances of the memory cells formed according to the method 2200 may be stacked over each other, such as in a repeating pattern. The various interconnections can be connected to form logical rows, columns, pages, blocks, and so forth.

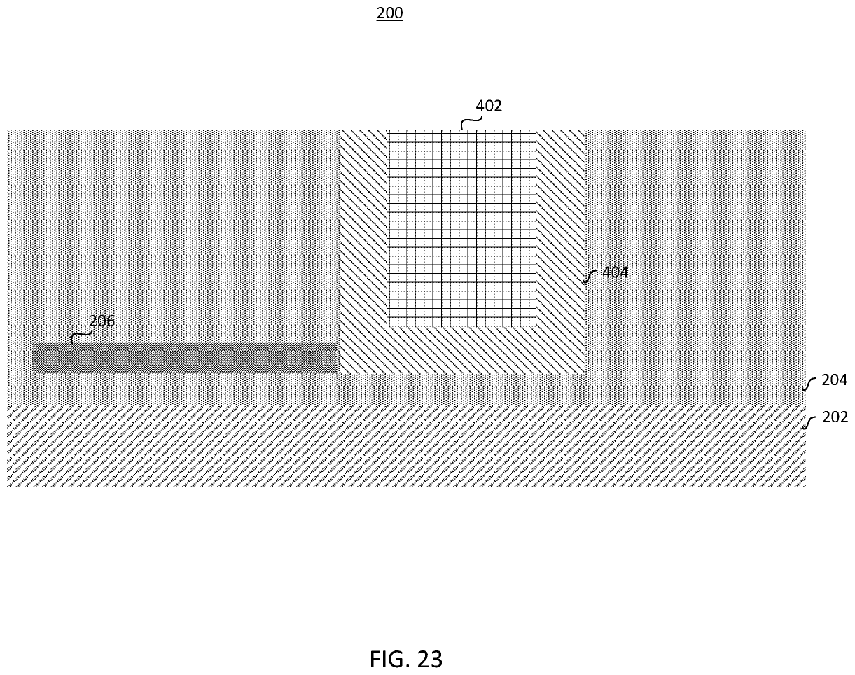

In various embodiments, operations of the method 2200 may be associated with top, or cross-sectional views of an example semiconductor device 200 at various fabrication stages as shown in FIGS. 23 to 28, which will be discussed in further detail below. It should be understood that the semiconductor device 200, shown in FIGS. 23 to 28, may include a number of other devices such as inductors, fuses, capacitors, coils, etc., while remaining within the scope of the present disclosure. For example, a semiconductor device 200 can include further layers of stacked transistors or channel portions thereof and interconnections therebetween.

In brief overview, the method 2200 starts with operation 2202 of forming a bottom electrode 206. The method 2200 continues to operation 2204 of forming a ferroelectric layer over the semiconductor device 200. The method 2200 continues to operation 2206 of forming a first gate electrode over the ferroelectric layer. The method 2200 continues to operation 2208 of forming a gate oxide layer. The method 2200 continues to operation 2210 of forming a gate dielectric layer. The method 2200 continues to operation 2212 of forming a second gate electrode. The method 2200 continues to operation 2214 of forming electrical contact portions. The method 2200 continues to operation 2216 of forming a first capacitor electrode. The method 2200 continues to operation 2218 of forming a capacitor dielectric. The method 2200 continues to operation 2220 of forming a second capacitor electrode. The method 2200 continues to operation 2222 of forming device interconnects.

Various operations depicted in FIG. 22 may be similar to other operations depicted in FIG. 1. The operations can be adjusted based on the gate location of FIG. 22. Accordingly, some operations of the method 2200 of FIG. 22 may be described briefly. One skilled in the art will realize that the various operations discussed with regard to the method 100 of FIG. 1 may be informative, in some respects, to the operations of the present method 2200. In some instances, explicit mention is made of a corresponding operation. Such mentions are not intended to limit the present method 2200. For example, some aspects of the method 100 of FIG. 1, which are not explicitly referred to are informative to the present method 2200, and some aspects which are explicitly mentioned are provided as illustrative examples, but can, according to various embodiments, be modified, omitted, or so forth. Further, like reference numbers are used for various features of the present method 2200, as for the method 100 of FIG. 1. Such references are not intended to be limiting. For example, some materials may vary between the various embodiments according to, for example, an abutting material which varies between a semiconductor device 200 formed according to the respective methods 100, 2200 of FIG. 1 and FIG. 22. Indeed, such materials may vary according to some embodiments of devices manufactured according to the method 100 of FIG. 1.

Corresponding to operations 2202, 2204, and 2206 of FIG. 22, FIG. 23 is a cross-sectional view of the semiconductor device 200 in which, at operation 2202, a metal structure of a bottom electrode 206 is formed. The bottom electrode 206 is spaced from a substrate 202 by a dielectric layer 204. At operation 2204, a ferroelectric structure 404 is formed over the semiconductor device 200. At operation 2206, a first gate structure 402 is formed.

The bottom electrode 206 may be formed according to a same or related operation or suboperation as is referred to with regard to FIG. 2 (e.g., operation 102). The operation can include forming an etch stop layer over a first portion of a dielectric layer 204 separating the bottom electrode 206 from the substrate 202. Thereafter, an opening can be formed alongside the bottom electrode 206. The ferroelectric structure 404 can be deposited according to a conformal process (e.g., ALD). A metal fill for the gate structure 402 can be formed over (e.g., in contact with) the ferroelectric structure 404. The ferroelectric material can be annealed to cause the ferroelectric structure 404 to exhibit a desired ferroelectric property prior or subsequent to depositing the metal fill for the gate structure 402. For example, an annealing process can be performed at operation 2204, or during another operation. Like various operations and suboperations, the annealing process can be omitted, in some embodiments. An upper surface of the semiconductor device 200 can be planarized to form the depicted surface.

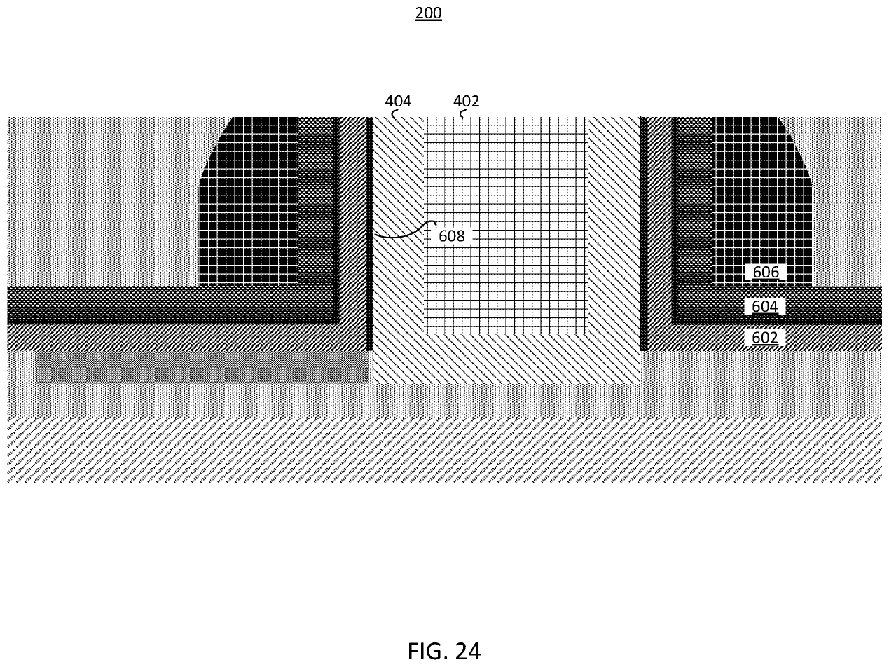

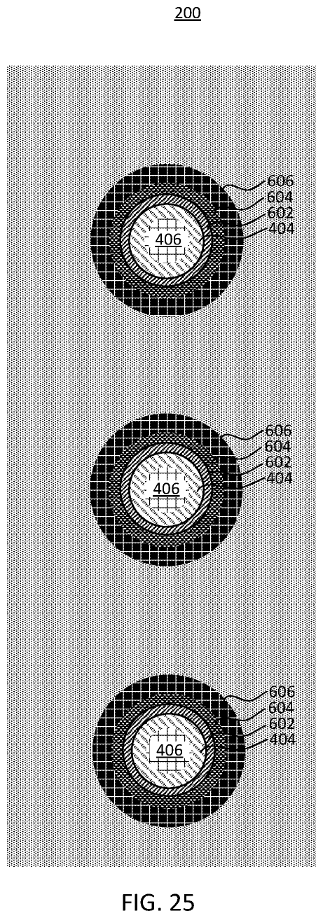

Corresponding to operations 2208, 2210, and 2212 of FIG. 22, FIG. 24 is a cross-sectional view of the semiconductor device 200 in which, at operation 2208, a gate oxide layer is formed over the semiconductor device 200. At operation 2210, a dielectric is formed over the gate oxide layer. At operation 2212, a metal fill is formed over the dielectric structure 604 to form another gate structure 606. FIG. 25 is a corresponding top view of the semiconductor device 200, in accordance with some embodiments.

The dielectric layer 204 is etched to a surface of the bottom electrode 206 (e.g., a etch stop layer, as discussed with regard to operation 102). For example, a wet etchant may be selected for an etchant speed, and a selectivity to the dielectric layer 204 relative to the etch stop or to a conductive material of the bottom electrode 206. Thereafter, at operation 2208, the semiconductor-behaving structure 602 is formed over the semiconductor device 200 (e.g., according to a conformal process described with regard to operation 108). At operation 2210, a dielectric structure 604 is formed over the semiconductor-behaving structure 602 (e.g., according to a conformal process is described with regard to operation 110). A metal fill for a second gate structure 606 can be formed according to a conformal or other process, such as another metal fill process (e.g., selective electroplating). A surface of the device can thereafter be planarized. As discussed with regard to FIG. 6, various interfacial dielectric layers 608 may separate or be included in various of the depicted layers. Likewise, such a layer can be directionally etched from the upper surface of the bottom electrode 206 such that the semiconductor-behaving structure 602 can be in contact with the bottom electrode 206, and electrically connected to the bottom electrode 206.

As depicted in FIG. 25, the planarization can reveal a surface of the semiconductor device 200 including a metal portion of a gate structure 406 for an inner gate circumscribed by, and concentric to, the ferroelectric structure 404. The ferroelectric structure 404, in turn, is circumscribed by, and concentric to, the semiconductor-behaving structure 602 (e.g., serving as a channel for the semiconductor device 200). The semiconductor-behaving structure 602 is, in turn, circumscribed by, and concentric to the dielectric structure 604. The dielectric structure 604, in turn, is circumscribed by, and concentric to, the metal portion of the outer gate structure 606. Thus, the semiconductor device 200 formed according to the present method 2200 includes inverted inner and outer gates relative to the semiconductor device 200 formed according to the method 100 of FIG. 1. According to various embodiments of the present disclosure, further geometries still are contemplated.

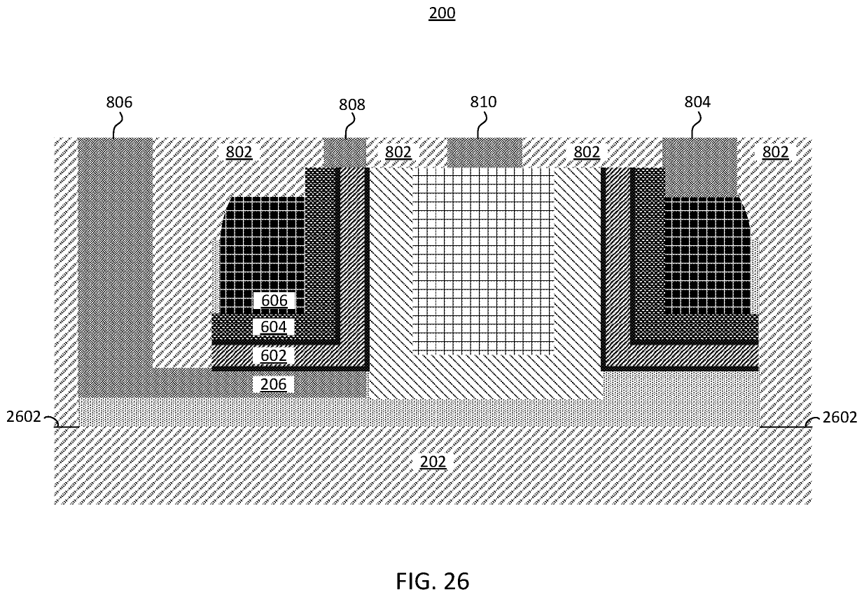

Corresponding to operation 2214 of FIG. 22, FIG. 26 is a cross-sectional view of the semiconductor device 200 in which, at operation 2214, various contacts are formed for the various structures of the semiconductor device 200, according to some embodiments.

Particularly, a first contact 804 is formed to electrically connect to the metal gate structure 606 of the outer gate. A second contact 806 is in contact with the bottom electrode 206 (e.g., through at least one dielectric layer 802). The second contact 806 can connect, via the bottom electrode 206, to a first face of the semiconductor-behaving structure 602 (e.g., a first drain/source). A third contact 808 can electrically connect to a second face of the semiconductor-behaving structure 602, opposite the first face, such that a channel is formed between the second contact 806 and the third contact 808, through the semiconductor-behaving structure 602. That is, the second contact 806 and third contact 808 can be source/drain contacts. A fourth contact 810 can electrically connect to a gate structure 402 for the inner gate.

According to the depicted view, the substrate 202 and one or more dielectric layers 802 are illustrated according to a same pattern. A junction line 2602 is provided to demarcate a junction therebetween. The junction line 2602 is not intended to depict a structure of the semiconductor device 200 (although, according to various embodiments, various additional layers can be included between various depicted portions including along the junction line 2602).

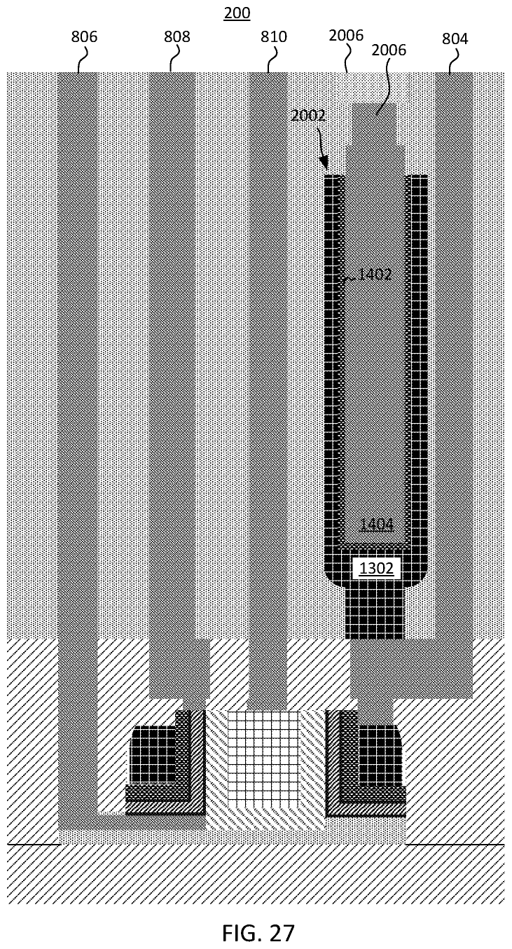

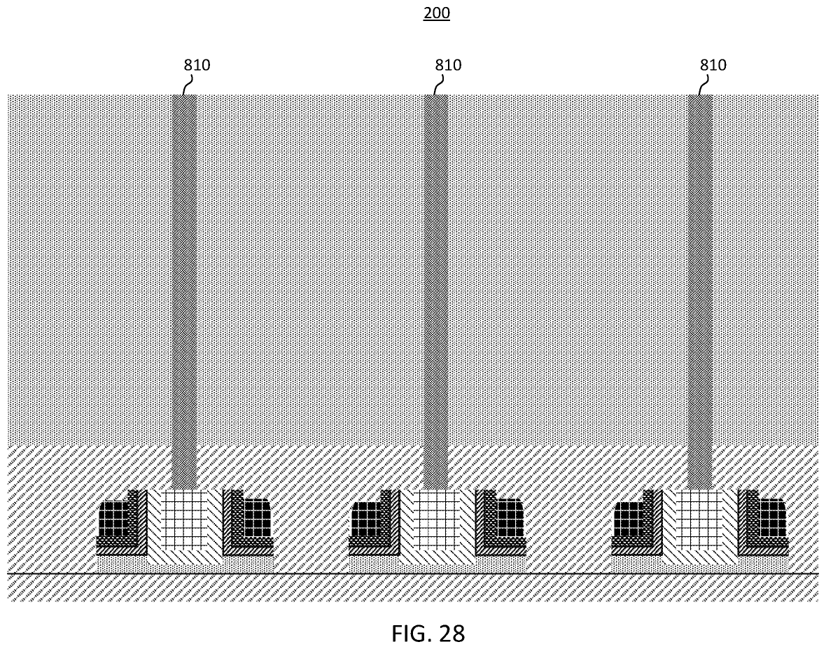

Corresponding to operations 2216, 2218, 2220, and 2222 of FIG. 22, FIG. 27 is a cross-sectional view of the semiconductor device 200 in which various contacts are extended to the surface of the semiconductor device 200, and a capacitor 2002 is formed. FIG. 28 is a corresponding cross-sectional view of the semiconductor device 200 along a perpendicular cut plane, in accordance with some embodiments.

Particularly, at operation 2216, a first capacitor electrode structure 1302 is formed, connected to the first contact 804. As depicted, the first capacitor electrode structure 1302 can be or include an outer layer electrode. For example, the first capacitor electrode structure 1302 can be formed according to one or more operations described with regard to operation 116 of the method 100 of FIG. 1. At operation 2218, a capacitor dielectric structure 1402 is formed along the first capacitor electrode structure 1302. For example, the capacitor dielectric structure 1402 can be formed according to one or more operations described with regard to operation 118 of the method 100 of FIG. 1. At operation 2220, a second capacitor electrode structure 1404 is formed along the dielectric. For example, the capacitor dielectric structure 1402 can be formed according to one or more operations described with regard to operation 120 of the method 100 of FIG. 1.

At operation 2222, various device interconnections are formed. The interconnections can include an interconnection between the various second capacitor electrodes 1404 of various capacitors, such as via a power rail 2004. The interconnections can include an extension of the first contact 804, the second contact 806, the third contact 808, the fourth contact 810, the power rail 2004, and the fifth contact 2006.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor device, comprising:
a first metal structure of a first gate electrode;
a gate dielectric structure:
extending along a bottom surface of the first metal structure; and
surrounding a sidewall of the first metal structure;
a semiconductor-behaving structure:
extending along a bottom surface of the gate dielectric structure; and
surrounding a sidewall of the gate dielectric structure;
a ferroelectric structure surrounding a sidewall of the semiconductor-behaving structure; and
a second gate electrode comprising a second metal structure in contact with the semiconductor-behaving structure.

2. The semiconductor device of claim 1, further comprising a capacitor, the capacitor comprising a third metal structure separated from the first metal structure by a capacitor dielectric structure.

3. The semiconductor device of claim 2, further comprising:
an electrical contact electrically connected to the first metal structure vertically extending parallel to the capacitor dielectric structure, the electrical contact serving as a first terminal of the capacitor, wherein the third metal structure serves as a second terminal of the capacitor.

4. The semiconductor device of claim 1, wherein:
the first metal structure is concentric to the sidewall of the gate dielectric structure;
the gate dielectric structure is concentric to the sidewall of the semiconductor-behaving structure;
the semiconductor-behaving structure is concentric to the ferroelectric structure; and
a capacitor dielectric structure is vertically spaced from the gate dielectric structure, the semiconductor-behaving structure, and the ferroelectric structure.

5. The semiconductor device of claim 4, further comprising:
a further dielectric structure circumscribing the second metal structure, wherein
the ferroelectric structure is concentric to, circumscribed by, and in contact with the second metal structure.

6. The semiconductor device of claim 2, wherein:
the third metal structure is connected to a plurality of further capacitor dielectric structures, the plurality of further capacitor dielectric structures configured to maintain a plurality of voltage levels.

7. The semiconductor device of claim 1, wherein:
the semiconductor-behaving structure comprises a conductive oxide.

8. The semiconductor device of claim 1, wherein:
a first source/drain contact extends beyond a lateral extreme of the semiconductor-behaving structure; and
the semiconductor-behaving structure extends beyond the first source/drain contact, opposite of the lateral extreme.

9. The semiconductor device of claim 2, wherein the capacitor dielectric structure and the gate dielectric structure comprise a same high-k dielectric material.

10. A semiconductor device, comprising:
a ferroelectric structure disposed around a second metal structure;
a semiconductor-behaving structure separated from a substrate, the semiconductor-behaving structure vertically extending along a sidewall of, and laterally away from, the ferroelectric structure;
a gate dielectric structure:
extending along an upper surface of the semiconductor-behaving structure; and
surrounding a sidewall of the semiconductor-behaving structure; and
a first metal structure surrounding a sidewall of the gate dielectric structure.

11. The semiconductor device of claim 10, further comprising:
a third metal structure vertically spaced from the first metal structure, the third metal structure separated from the first metal structure by a capacitor dielectric structure;
an electrical contact electrically connected to the first metal structure vertically extending parallel to a sidewall of the third metal structure, the electrical contact serving as a first terminal of a capacitor, wherein the third metal structure serves as a second terminal of the capacitor.

12. The semiconductor device of claim 10, further comprising:
a first dielectric structure interposed between a source/drain contact and the substrate.

13. The semiconductor device of claim 11, wherein the capacitor dielectric structure and the gate dielectric structure comprise a same high-k dielectric material.

14. The semiconductor device of claim 10, wherein:
the second metal structure is circumscribed by the ferroelectric structure;
the ferroelectric structure is concentric to, and circumscribed by, the semiconductor-behaving structure;
the semiconductor-behaving structure is concentric to, and circumscribed by, a third dielectric structure; and
the third dielectric structure is concentric to, and circumscribed by the first metal structure.

15. The semiconductor device of claim 10, wherein:
the semiconductor-behaving structure comprises a conductive oxide.

16. A method for fabricating semiconductor devices, comprising:
forming a ferroelectric structure over, and spaced from, a substrate;
forming a semiconductor-behaving structure laterally spaced from the ferroelectric structure;
forming a first gate structure comprising a first metal portion, the first gate structure conforming to the semiconductor-behaving structure along a first portion of the semiconductor-behaving structure extending in a vertical direction, and a second portion of the semiconductor-behaving structure extending perpendicular to the first portion of the semiconductor-behaving structure;
forming a second gate structure comprising a second metal portion, the second gate structure conforming to the ferroelectric structure along a first portion of the ferroelectric structure extending in the vertical direction, and a second portion of the ferroelectric structure extending perpendicular to the first portion of the ferroelectric structure;
forming a vertical sidewall electrically connected to the first gate structure, and a first electrical contact extending parallel to the vertical sidewall;
forming a high-k dielectric along the vertical sidewall; and
forming a terminal comprising a third metal portion over the high-k dielectric.

17. The method of claim 16, further comprising:
forming a second electrical contact between the substrate and the semiconductor-behaving structure, extending laterally beyond an extreme of the semiconductor-behaving structure, the second electrical contact in contact with the semiconductor-behaving structure along a first face;
forming a third electrical contact between a second face of the semiconductor-behaving structure, opposite from the first face;
forming a fourth electrical contact in contact with the second metal portion; and
forming a fifth electrical contact in electrical contact with the third metal portion, wherein
the first electrical contact, the second electrical contact, the third electrical contact, and the fourth electrical contact extend upwardly beyond a vertical extreme of the high-k dielectric.

18. The method of claim 16, further comprising:
forming a rail connecting the third metal portion with a plurality of further third metal portions.

19. The method of claim 16, wherein:
the ferroelectric structure is formed along an inner sidewall of the second metal portion;
the semiconductor-behaving structure is formed over an inner sidewall of the ferroelectric structure; and
the first metal portion is formed over an inner sidewall of the semiconductor-behaving structure.

20. The method of claim 16, wherein:
the semiconductor-behaving structure is formed over an outer sidewall of the ferroelectric structure; and
the first metal portion is formed over an outer sidewall of the semiconductor-behaving structure.
